(19) United States
(12) Patent Application Publication
(10) Pub. No.: US 2009/0040578 A1
(43) Pub. Date: Feb. 12, 2009

(54) Hologram and Its Method of Manufacture

(76) Inventor: Robert Adam Munday, Surrey (GB)

Correspondence Address: Manelli Denison & Selter;Attn: William H. Bollman, 2000 M Street, NW, 7th Floor, Washington, DC, 20036, US

(21) Appl. No.: 11/886,745

(22) PCT Filed: Mar. 23, 2006
(86) PCT No.: PCT/GB2006/001039

§ 371 Date: Sep. 20, 2007

(30) Foreign Application Priority Data
Mar. 23, 2005 (GB) 0506003.3

(51) Int. Cl. G02B 5/32; G03F 7/00

(52) U.S. Cl. 359/15; 430/2

(57) ABSTRACT

The present invention relates to a holographic display whereby a holographic image may be viewed. Existing holographic optical element (HOE) arrays are typically recorded as a two dimensional array. Each element in the array modulates the intensity of light that is transmitted through or off it. Each HOE in a simple HOE array auto-stereogram performs only one optical function, namely to redirect light to a particular viewing location in space. The process of producing HOE arrays was limited in a number of respects. The invention overcomes these limitations by providing an intensity modulated holographic optical element array, comprising: an holographic optical element (12) adapted to modify the direction of light reflected from elements in the array; and a means (18) for modulating the intensity of the reflected light. A method of producing an intensity modulated holographic optical element array is also described. The invention may also be used in transmissive holograms.

### BACKGROUND

The present invention relates to a hologram and its method of manufacture. More particularly, but not exclusively, the invention relates to a holographic optical element whereby a holographic image may be viewed. The image may be printed on a substrate, displayed on a display or projected on a screen.

A hologram is a technique of recording and reproducing three-dimensional images using light from a laser, but one which does not require cameras or lenses in order to replay the hologram. Holographic images are generated by two beams of light producing interference patterns. A single beam of laser or coherent light is split into two beams. One beam is reflected onto the object and then onto a photographic film or plate. The second beam, the reference beam, is passed straight on to the film or plate. The interference pattern that is recorded on the film or plate is called a hologram. The developed film or plate, when illuminated with light, reproduces the three dimensional image because the interference patterns effect the light so as to reconstruct a three dimensional image of the original object.

### PRIOR ART

Other ways have been found for creating a holographic image. For example, a holographic lens array, commonly called a digital, direct write or dot matrix hologram, have been known and employed since around the mid 1980's.

A holographic lens array or holographic optical element array (hereinafter called an HOE array) comprises a multiplicity of holographic lenses or pixels recorded in an array. Each holographic lens is a small, single, diffractive or refractive element or micro-lens (hereinafter called an HOE). The multitude of HOE arrays are recorded as a two dimensional array which can have any pattern or layout. Each element in the array modulates the intensity of the light that is transmitted through it, or off, it and redirects the modulated light to a particular position or viewing zone in space. The precise light modulation and light direction for each HOE array can be predetermined when the hologram is made.

HOE arrays have been used to create auto-stereoscopic (three-dimensional) holographic images and displays. Early dot-matrix hologram patterns (HOE arrays) displayed three-dimensional stereoscopic effects by accident. Later, the principle was intentionally used to create such images and displays.

The simplest such holographic image or display involves splicing together two pixellated stereoscopic images comprising a left view image and a right view image in such a way that each image is spatially separate within the resultant image. The spliced image is then recorded as an HOE array. Each pixel in the image is recorded as an HOE such that light from the left view image pixels or HOE arrive at a position in space corresponding to the left eye position of the observer; and light from the right view image pixels or HOEs arrive at a position in space corresponding to the right eye position of the observer. Once the HOE array is illuminated, all of the light which corresponds to the left eye image is seen only by the left eye of the observer and all of the light corresponding to the right eye image is seen only by the right eye of the observer, creating a stereoscopic image seen by the observer. By employing more than two stereoscopic images at once, full colour auto-stereoscopic (three-dimensional) holographic images have been produced which contain parallax.

Each HOE in a simple HOE array auto-stereogram performs only one optical function, namely to redirect light that is transmitted though each HOE in the array to a particular viewing location in space. This permits production of “graphic” auto-stereogram images that contain no shading or tonal range. To produce shaded auto-stereograms it has been necessary to record HOEs within the array that also selectively modulate the intensity of light diffracted through, or refracted from, the HOE. This has been achieved by manipulating the diffraction efficiency of each HOE as it was recorded by modulating the size of each HOE whilst it was being recorded or by modulating the depth of the interference fringes.

The smaller the HOE, or the shallower the fringes, the less light that was diffracted or refracted to its particular viewing zone; and the larger the HOE, or deeper the fringes, the more light that is diffracted or refracted to its particular viewing zone. This method allows production of shaded auto-stereoscopic HOE displays with parallax.

Despite the success of the aforementioned HOE arrays the process of producing them was limited in a number of respects, in particular the process was not flexible and mass production of different HOE arrays was not possible.

The present invention seeks to overcome these problems and one aim of the present invention is to provide an improved intensity modulated HOE array type holographic images and displays.

Another aim of the present invention is to provide an improved method of producing intensity modulated HOE array type holographic images and displays.

### SUMMARY OF THE INVENTION

According to a first aspect of the present invention there is provided: a hologram comprising: a holographic optical element (HOE) array adapted to modify the direction of light reflected from elements in the array; and an intensity modulating image filter, in registration with the holographic optical element array.

According to a second aspect of the present invention there is provided a hologram comprising: a holographic optical element (HOE) array adapted to modify the direction of light transmitted through elements in the array; and an intensity modulating image filter, in registration with the holographic optical element array.

As a result of the elements of an array being positioned in registration with light modulating elements, the invention overcomes the limitations of existing holography by making it possible to mass reproduce holograms where each hologram is unique.

The present invention also provides a new mass replication method for holograms whereby each hologram can be unique, one to another, and extremely inexpensive.

According to a third aspect of the present invention there is provided: a method of manufacturing a hologram comprising: the steps of forming a holographic optical element (HOE) array adapted to modify the direction of light reflected from elements in the array; and forming an intensity modulating image filter, in registration with the holographic optical element array.

According to a fourth aspect of the present invention there is provided a method of manufacturing a hologram comprising: forming a holographic optical element (HOE) array adapted to modify the direction of light transmitted through elements in the array; and forming an intensity modulating image filter, in registration with the holographic optical element array.

According to a yet further aspect, the invention comprises a holographic display for producing a shaded holographic image comprising: a light directing holographic optical element (HOE) array, operative to produce an unshaded three dimensional image when illuminated; and an optical intensity modulating image filter positioned in registration with the HOE array.

Preferably the invention further provides that an intensity modulating image filter may be electronically adjustable, and can comprise a spatial light modulator (SLM) such as a liquid crystal display (LCD), liquid crystal on silicon (LCOS) or other such electronic display. The properties of an applied electronic optical intensity modulating image filter can be adjusted to update a resultant holographic image, which can, for example, be an auto-stereoscopic image that optionally may have parallax.

The invention further provides that the intensity modulating image filter can be electronically adjustable, and can comprise electronic ink applied by a printing process. Electronic ink is one that is capable of conducting an electric current and when so doing modifies at least one of its physical properties, such as its tone, colour, magnetic, optical or electrical characteristic.

Preferably the invention further provides that electronic ink can be ink whose reflective or transmissive properties can be selectively modulated by applying an electric charge. By the electric charge making the particles of ink more or less reflective or transmissive (and thus more or less black or white to reflected or transmitted incident optical radiation), the properties of an applied optical intensity modulating image filter can be adjusted to update the produced holographic image, which can, for example, be an auto-stereoscopic image which can have parallax.

The invention may also provide that the printing process can comprise, where required, preliminary deposition of an ink receptive coating.

As the invention may be adapted to employ any existing type of printing process, for example ink-jet, offset litho or laser printing, ordinary ink may be used in the process. The image filter could also be made using a photographic imaging process.

Preferably the invention also provides that the HOE array can be fabricated by a process which involves at least one of: embossing; photographic exposure, e.g. of silver halide or photo-polymer material; casting; electroforming and laser ablation.

The invention also provides that the HOE array can be provided on a HOE substrate, and that the HOE substrate can be a separate substrate whereon the HOE array is deposited, or can be a product of the HOE array preparation itself such as part of a casting process.

Advantageously the invention further provides that the optical intensity modulating image filter can be applied to an optical intensity modulating image filter substrate which can be attached to the HOE substrate, the optical intensity modulating image filter substrate being attachable to the HOE array substrate by a process involving at least one of: lamination; clamping; gluing; gluing at discrete points, or simply placing together.

The invention further provides that the optical intensity modulating image filter can be attached to a second face of the HOE substrate, or that a second face of the optical intensity modulating image filter substrate can be attached to the second face of the HOE substrate.

Preferably the invention further provides that the optical intensity modulating image filter may be applied to the HOE substrate, and can be applied to the HOE array. The invention also provides for provision of a reflective layer, that the reflective layer can be applied to the HOE substrate or to the optical intensity modulating image filter substrate, to provide for reflective viewing.

The invention may further provide that the HOE substrate can be transparent, opaque or reflective. The invention further provides that the optical intensity modulating image filter substrate can be transparent, opaque or reflective.

In a particularly preferred embodiment the invention further provides that the optical intensity modulating image filter substrate can be a spaced substrate from the HOE substrate, a projected image of the optical intensity modulating filter being projected from a distance onto the HOE array.

In an alternative embodiment the invention provides that the projected image can be by transmission through the optical intensity modulating image filter substrate, can be by reflection from the optical intensity modulating image filter, or can be by reflection from the optical intensity modulating image filter through the optical intensity modulating image filter.

Preferably the HOEs can be applied directly to the applied optical intensity modulating filter.

The invention also provides that the holographic image can comprise at least one of: a simple holographic image; an auto stereo holographic image; and an auto stereo holographic image with parallax.

The invention further provides that the optical intensity modulating image filter can be fabricated by laser ablation of a HOE array to alter the reflective or transmissive properties of the individual HOE.

The invention further provides that the optical intensity modulating image filter can be fabricated by laser ablation of an optical intensity modulating image filter layer beneath a HOE array by means of a focused laser, and that the optical intensity modulating image filter layer can be opaque or reflective.

Preferably the optical intensity modulating image filter can be fabricated by focused laser ablation of an opaque layer on a HOE array, and that the opaque layer can also be reflective.

Preferred embodiments of the invention will now be described, by way of several examples, and with reference to the Figures, in which:

### BRIEF DESCRIPTION OF THE FIGURES

FIG. 1 is an isometric view of an exemplary display, according to the invention showing a HOE layer on a substrate;

FIGS. 2A to 2D form a series of cross sectional side views showing stages of fabrication of a first embodiment of the invention where the optical intensity modulating image filter is provided atop the HOE layer;

FIGS. 3A to 3D form a series of cross sectional side views showing stages of fabrication of a second embodiment of the invention where the optical intensity modulating image filter is provided on an opposite side of the HOE substrate;

FIG. 4A shows a cross sectional side view of the exploded parts of examples of third and fourth embodiments of the invention where the optical intensity modulating image filter is provided on an optical intensity modulating image filter substrate;

FIG. 4B showing a cross sectional side view of a third embodiment of the invention where the optical intensity modulating image filter is provided on the outside of a blank-side sandwich of the HOE substrate and the optical intensity modulating image filter substrate;

FIG. 4C showing a cross sectional side view of a fourth embodiment of the invention where the optical intensity modulating image filter is provided between the HOE substrate and the optical intensity modulating image filter substrate;

FIG. 5 shows a cross sectional side view of a fifth embodiment of the invention where the optical intensity modulating image filter is applied directly to the HOE layer;

FIGS. 6A and 6B show the stages of fabrication of a sixth embodiment of the invention where HOE layer and the optical intensity modulating image filter can be separately formed by means of a laser ablating tool with selectable focal depth and/or selectable power;

FIG. 7 shows a cross sectional side view of a seventh embodiment of the invention wherein a laser is used to damage a HOE layer to alter the reflective or refractive properties of each HOE, thereby to create the optical intensity modulating image filter;

FIG. 8 shows a cross sectional side view of an eight embodiment of the invention, where an opaque layer is laser ablated to provide the optical intensity modulating image filter; and

FIG. 9 shows a cross sectional view of a ninth embodiment of the invention where the optical intensity modulating image filter is on an optical intensity modulating image filter substrate and has its image projected onto the HOE.

### DETAILED DESCRIPTION OF PREFERRED EMBODIMENTS OF THE INVENTION

Reference is made firstly to FIG. 1, showing an isometric view of an exemplary display, according to one aspect of the invention having a HOE layer on a substrate.

A HOE substrate 10 has a HOE array 12 provided on a first face 14. The HOE substrate 10 can be opaque, reflective or transparent, depending upon the style of the display, as will become evident from subsequent description. The manner of fabrication of the HOE array 12 can be many and varied, and comprises all known means of creating a HOE array 12, including, but not limited to, embossing, photographic exposure, e.g. of silver halide or photo-polymer material, casting, electroforming, laser ablation, and so on. The HOE substrate 12 can be a separate substrate whereon the HOE array is provided, or may be a product of the HOE array preparation itself such as part of a casting process.

The HOE array 12 can be representative of any type of holographic image, be it a non-three dimensional image, a three-dimensional image, an auto-stereographic image, or an auto-stereographic image with parallax. For preference, the image provided by the HOE array 12 is an auto-stereographic image with parallax.

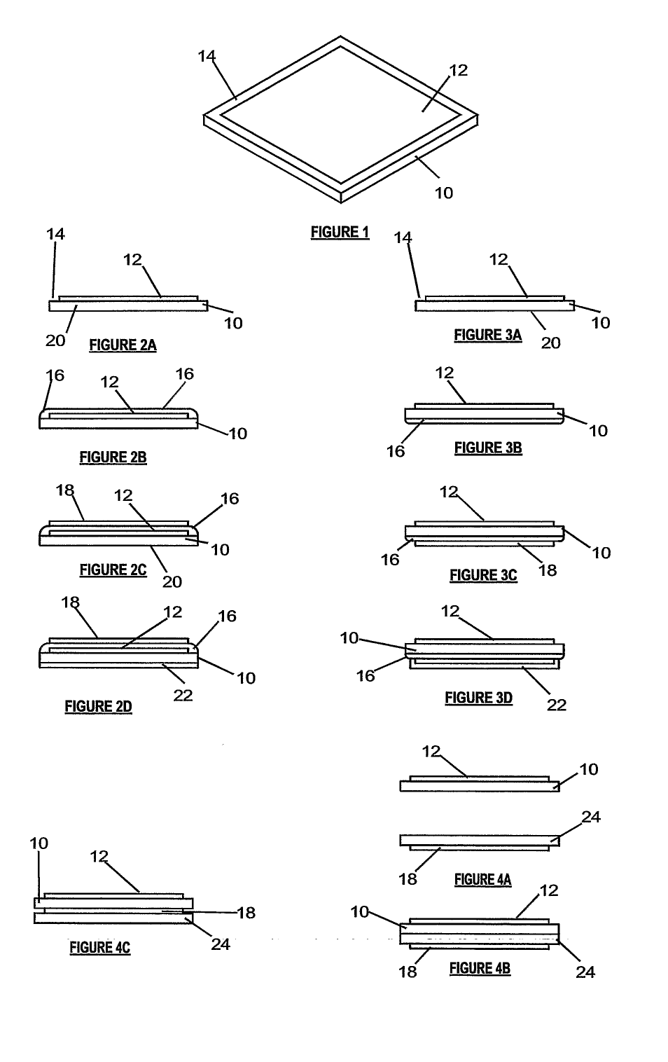

Referring next to FIGS. 2A to 2D, which show a series of cross sectional side views showing stages of fabrication of a first embodiment of the invention where the optical intensity modulating image filter is provided atop the HOE layer.

FIG. 2A shows a cross sectional side view of FIG. 1, with the HOE array 12 atop a first side 14 of the HOE substrate 10. FIG. 2B shows how an ink receptive coating 16 is laid over the HOE array 12 to provide adhesion of the ink used to deposit the optical intensity modulating image filter 18 atop the ink receptive coating 18 shown in FIG. 2C. The optical intensity modulating image filter 18 is laid down by an ink jet printer. The ink jet printer can merely use opaque ink, but for preference uses electronic ink whose reflective or transmissive properties can be selectively modulated by applying an electric charge. The optical intensity modulating image filter 18 is laid down in exact registration with the HOE array, thereby to provide the required degree of shading to the resultant holographic image.

The display shown in FIG. 2C is now viewable by transmissive viewing provided that the HOE substrate 10 is transparent and the viewing light, which does not have to be a coherent light, is provided through the HOE substrate 12 from a second face 20 of the HOE substrate 12, the image observer being in the direction of the first face 14 of the HOE substrate 12.

FIG. 2D shows a further addition permitting reflective viewing. A reflective layer 22 is provided on the second face 20 of the HOE substrate 10. Light passes through the HOE substrate, is reflected by the reflective layer 22, and passes through the HOE array 12 and the optical intensity modulating image filter 18 to provide the required image.

As a modification to FIG. 2D, the reflective layer 22 can be omitted, and the HOE substrate 12 itself made of a reflective material, to achieve much the same effect, but without viewing light having to traverse the thickness of the HOE substrate 12.

The ink receptive coating 16 is optional, being omitted when the type of ink used does not require its provision.

Referring now to FIGS. 3A to 3D, showing a series of cross sectional side views of stages of fabrication of a second embodiment of the invention where the optical intensity modulating image filter is provided on the second face 20 the HOE layer 12.

Just as FIG. 2A, FIG. 3A shows a cross sectional side view of FIG. 1, with the HOE array 12 atop a first side 14 of the HOE substrate 10. FIG. 3B shows how, if required, an ink receptive coating 16 is provided on the second face 20 of the HOE substrate. In this embodiment, the HOE substrate 12 must be transparent. FIG. 3C shows how the optical intensity modulating image filter 18 is next applied on the second face 20 of the HOE substrate. The display shown in FIG. 3C is now viewable by transmissive viewing provided that the viewing light (not necessary to be coherent light) is provided through the HOE substrate 12 from the second face 20 of the HOE substrate 12, the image observer being in the direction of the first face 14 of the HOE substrate 12.

FIG. 2D shows an addition to FIG. 3C permitting reflective viewing. A reflective layer 22 is applied over the optical intensity modulating image filter 18 on the second face 20 of HOE substrate 10 to reflect light, received through the HOE substrate 10, back through the optical intensity modulating image filter 18 and the HOE array 12, to make an image visible to an observer in the direction of the front face 14 of the HOE substrate 10.

Attention is next drawn to FIG. 4A showing a cross sectional side view of the exploded parts of the basis of third and fourth embodiments of the invention where the optical intensity modulating image filter 18 is provided on an optical intensity modulating image filter substrate 24.

Attention is next drawn to FIG. 4B showing a cross sectional side view of the third embodiment of the invention where the optical intensity modulating image filter 18 is provided on the outside of a blank-side sandwich of the HOE substrate 10 and the optical intensity modulating image filter substrate 24, both of which are transparent. A reflective layer 22 can be added to enable transmissive viewing. The HOE substrate 12 and the optical intensity modulating image filter substrate 24 can be laminated, clamped, glued, glued at discreet points, or simply placed together. A small gap can be left between the HOE substrate 12 and the optical intensity modulating image filter substrate 24, though this is not preferred.

Attention is next drawn to FIG. 4C showing a cross sectional side view of a fourth embodiment of the invention where the optical intensity modulating image filter 18 is provided between the HOE substrate 10 and the optical intensity modulating image filter substrate 24. Both the HOE substrate 10 and the optical intensity modulating image filter substrate 24 must be transparent for transmissive viewing but the optical intensity modulating image filter substrate 24 can be of reflective material for reflective viewing. The HOE substrate 12 and the optical intensity modulating image filter 18 can be laminated, clamped, glued, glued at discreet points, or simply placed together. A small gap can be left between the HOE substrate 12 and the optical intensity modulating image filter 18, though this is not preferred.

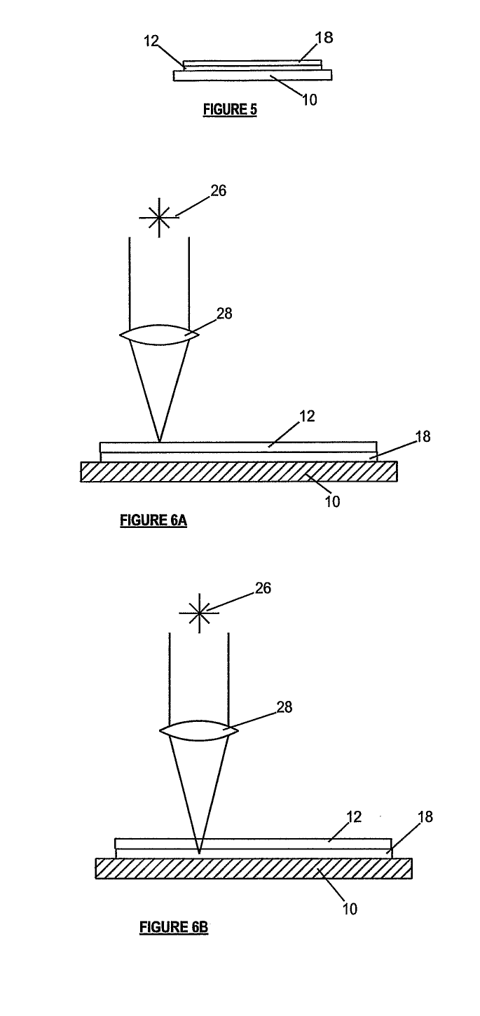

Attention is next drawn to FIG. 5, showing a cross sectional side view of a fifth embodiment of the invention where the optical intensity modulating image filter 18 is applied directly to the HOE array 12 layer. Instead of employing an ink receptive coating, as shown in FIGS. 2A-2D and 3A-3D, the optical intensity modulating image filter 18 is deposited directly onto the HOE array 12. Alternatively, the optical intensity modulating image filter 12 can be fabricated by photographic means, for example, photo-polymer or silver halide being laid down upon the HOE array 12 and exposed and developed in-situ.

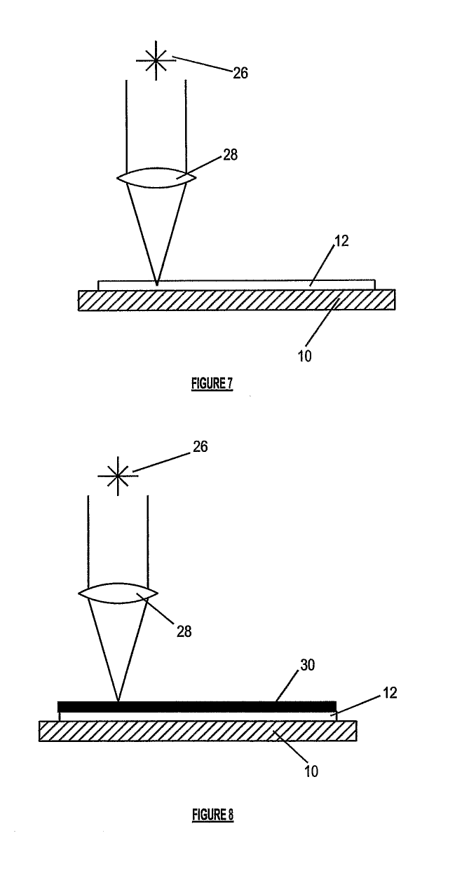

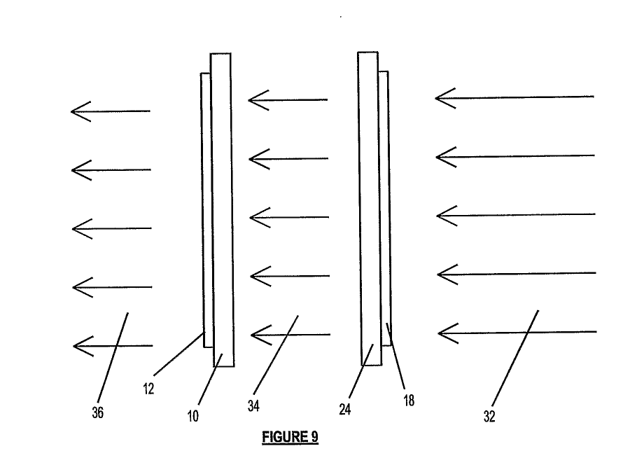

Attention is next drawn to FIGS. 6A and 6B, showing stages of fabrication of a sixth embodiment of the invention where HOE array 12 layer and the optical intensity modulating image filter 18 are separately formed by means of a laser ablating tool with selectable focal depth.

FIG. 6A shows a first stage in fabrication of the sixth embodiment of the invention in which the intensity modulation layer is produced. Laser light source 26 is focussed by a lens 28 onto the HOE array 12 layer. The laser light source 26, when focused, is of sufficient intensity to ablate (cause to be removed by vaporisation) the material of the HOE array 12 layer. The fineness of the focus of the laser light source 26 is such that, when focussed onto one layer, the focused laser light source 26 cannot cause ablation of any adjacent layer. The HOE array 12 is created by moving a combination of the laser light source 26 and the lens 28 from place to place across the HOE array 12 layer and by suitably modulating the intensity of the laser light source 26.

FIG. 6B shows a second stage in fabrication of the sixth embodiment of the invention. The optical intensity modulating image filter 18 layer is laid upon the HOE substrate 12 beneath the HOE array 12 layer. This is achieved by first laying down the optical intensity modulating image filter 18 layer onto the HOE substrate 10 and then laying the HOE array 12 layer over it. The combination of the laser light source 26 and the lens 28 is moved to shift the focus into the optical intensity modulating image filter 18 layer. Alternatively, only the lens needs to be moved in relation to the laser light source 26 in order to shift the focus. The optical intensity modulating image filter 18 is created by moving the combination of the laser light source 26 and the lens 28 from place to place across the optical intensity modulating image filter 18 layer and by suitably modulating the intensity of the laser light source 26.

In alternative embodiments layers or portions of material may be removed for example by ablation using either a particle beam or a laser removal technique. The amount (size) of a volume of material and/or the area/depth of a piece of removed material can be chosen in order to affect the optical properties of the array.

The sixth embodiment has been show using laser ablation to form both the HOE array 12 and the optical intensity modulating image filter 18. It is to be understood that the HOE array 12 can be formed by any other suitable means, only the optical intensity modulating image filter 18 being formed by laser ablation. The HOE substrate 10 can be transparent for transmissive viewing, transparent with the addition of a reflective layer 22 on its second face 20 for reflective viewing, opaque or transparent with a reflective layer immediately beneath the optical intensity modulating image filter 18 layer also for reflective viewing, or optically reflective for reflective viewing.

In addition, the sixth embodiment offers the option of a further embodiment, where the optical intensity modulating image filter 18 layer is made from reflective material, allowing reflective viewing without the addition of any reflective layer 22 or of providing a reflective HOE substrate 10.

Attention is next drawn to FIG. 7, showing a cross sectional side view of a seventh embodiment of the invention wherein a laser is used to damage a HOE array 12 or alter the transmissive or refractive properties of each HOE, thereby to create the optical intensity modulating image filter 18. The HOE array 12 is formed by any means already described. A lens 28 focussed laser light source 26, focused onto the HOE array 12, is then moved from place to place across the HOE array 12, and by suitably modulating the intensity of the laser light source 26, the reflectivity or transmissivity of each HOE is changed to implement the optical intensity modulating image filter 18, this time as a modification to the properties of each HOE.

In the seventh embodiment, the HOE substrate 10 can be transparent for transmissive viewing, transparent with the addition of a reflective layer 22 on its second face 20 for reflective viewing, opaque or transparent with a reflective layer immediately beneath the HOE layer also for reflective viewing, or optically reflective for reflective viewing.

Attention is next drawn to FIG. 8, showing a cross sectional side view of an eight embodiment of the invention, where an opaque layer is laser ablated to provide the optical intensity modulating image filter 18.

The HOE array 12 is provided using any of the means described above. An opaque, laser ablatable layer 30 is coated on top of the HOE array 12. The optical intensity modulating image filter 18 is created by moving the combination of the laser light source 26 and the lens 28 from place to place across the opaque layer and by suitably modulating the intensity of the laser light source 26 to ablate the opaque layer to leave the optical intensity modulating image filter 18 on top of the HOE array 12. As an alternative, the opaque layer 30 can be chemically etched or its fabrication can involve a photographic process.

In the eighth embodiment, the HOE substrate 10 can be transparent for transmissive viewing, transparent with the addition of a reflective layer 22 on its second face 20 for reflective viewing, opaque or transparent with a reflective layer immediately beneath the HOE array 12 also for reflective viewing, or optically reflective for reflective viewing. The opaque layer 30 can also be reflective for transmissive or reflective viewing.

Attention is finally drawn to FIG. 9, showing a cross sectional view of a ninth embodiment of the invention where the optical intensity modulating image filter 18 is on a separate optical intensity modulating image filter substrate 24 and has its image projected onto the HOE array 12.

Just as with FIGS. 4A, 4B and 4C, the HOE array 12 is provided on a HOE substrate 10 and the optical intensity modulating image filter 18 is provided on an optical intensity modulating image filter substrate 24. The optical intensity modulating image filter substrate 24 and the HOE substrate 10 are separated. The image of the optical intensity modulating image filter 18 is projected onto the HOE array 12 by incoming light 32 being intensity modulated by the optical intensity modulating image filter 18 to provide modulated light 34 which passes through the HOE array 12 to provide output light 36 forming the image to be viewed.

The ninth embodiment, in FIG. 9, shows the optical intensity modulating image filter substrate 24 and the HOE substrate 10 being back to back. It is to be understood that one, the other, or both can be turned around.

The embodiment shown in FIG. 9 can also be implemented in other ways. For example, the optical intensity modulating image filter substrate can be made reflective, by any of the means before described, and used to modulate incoming light 32 as modulated light 34 onto the HOE array 12, from which output light 36 which can be viewed in transmission by the HOE array 12 itself transparent or from which output light 36 can be viewed reflectively by the HOE array 12 being rendered reflective by any of the means before described.

The invention has been explained and described by way of a plurality of embodiments. The plurality of embodiments cannot be exhaustive, and it is to be understood that the invention also consists in and comprises any of the measure described above taken singly, or in any combination.

1. A hologram comprising: a holographic optical element (HOE) array adapted to modify the direction of light reflected from elements in the array; and an intensity modulating image filter, in registration with the holographic optical element array.

2. A hologram comprising: a holographic optical element (HOE) array adapted to modify the direction of light transmitted through elements in the array; and an intensity modulating image filter, in registration with the holographic optical element array.

3. A hologram according to claim 1 wherein the intensity modulating image filter is electronically adjustable.

4. A hologram according to claim 3 wherein the intensity modulating image filter is from the group comprising: a spatial light modulator (SLM), a liquid crystal display (LCD) and a liquid crystal on silicon display (LCOS).

5. A hologram according to claim 4 wherein the holographic optical element (HOE) array has at least two viewing zones; and a means for introducing regions of variable optical image data into each zone.

6. A hologram according to claim 5 wherein the holographic optical element (HOE) array has at least two viewing zones; and a means for introducing parallax into each zone.

7. A hologram according to claim 1 wherein the intensity modulating image filter includes electronic ink or thermochromic ink.

8. A hologram according to claim 7 wherein the ink is adapted to conduct an electric current and, in use, modifies at least one of its physical properties.

9. A display according to claim 8 wherein the ink modifies at least one of its physical properties, from the group comprising: tone, colour, magnetic, electrical, optical reflectivity and optical transmissivity.

10. A method of producing a hologram comprising the steps of: forming an holographic optical element (HOE) array; overlaying, in registration with said array, an intensity modulating image filter, adapted to modify the intensity of light reflected by the holographic optical elements of the array.

11. A method of producing a hologram comprising the steps of: forming an holographic optical element (HOE) array; overlaying, in registration with said array, an intensity modulated image filter, adapted to modify the intensity of light transmitted through the holographic optical elements of the array.

12. A method according to claim 10 wherein the intensity image modulating image filter is arranged to be printed in an array of elements so as to be in registration with the HOE array.

13. A method of producing a hologram according to claim 12 wherein a preliminary deposition of an ink receptive coating is provided on a substrate that receives ink.

14. A method according to claim 10 employs printing processes from the group comprising: ink-jet printing, offset lithographic printing, laser printing, Gravieux printing and dye sublimation printing.

15. A method according to claim 10 employing a photographic imaging process for producing the intensity modulating image filter.

16. A method according to claim 10 employing laser ablation for producing the intensity modulating image filter.

17. A method according to claim 10 wherein the HOE array is fabricated by at least one of the techniques in the group comprising: embossing, vacuum forming, photographic exposure, injection moulding, casting, electroforming, electron beam ablation and laser ablation.

18. A method according to claim 10 includes applying the intensity modulating image filter substrate to a substrate on the HOE array by a process involving at least one of the techniques from the group comprising: bonding, laminating, clamping, gluing, gluing at discrete points and cohering.

19. A method according to claim 11 including the steps of modifying mass produced holograms by introducing a characteristic so that individual unique holograms are formed.

20. A method according to claim 19 including the steps of modifying mass produced holograms by introducing a random characteristic so that individual unique holograms are formed.

21. A method according to claim 19 including the steps of modifying mass produced holograms by introducing a sequential characteristic so that individual unique holograms are formed.

22. (canceled)

23. (canceled)
